(19) United States
(12) Patent Application Publication
(10) Pub. No.: US 2015/0369887 A1
(43) Pub. Date: Dec. 24, 2015

(54) Methods and apparatuses related to instrumentation for magnetic relaxometry measurements

(71) Applicant: Senior Scientific LLC, Albuquerque, NM (US)

(72) Inventors: Todor Karaulanov, Albuquerque, NM (US); Edward R. Flynn, Peioria, AZ (US)

(21) Appl. No.: 14/744,306

(22) Filed: Jun. 19, 2015

Related U.S. Application Data
(60) Provisional application No. 62/014,634, filed on Jun. 19, 2014.

(51) Int. Cl. G01R 33/3815; G01R 33/34; G01R 33/24

(52) U.S. Cl. CPC G01R 33/3815; G01R 33/24; G01R 33/34061

(57) ABSTRACT

Embodiments of the invention provide methods and apparatuses suitable for use with magnetic relaxometry measurements. Embodiments can include one or more of atomic magnetometers, synthetic gradiometers, specific magnetizing coil configurations, cryoswitches, shielded enclosures, and field compensation systems.

The present invention is related to magnetic relaxometry and associated methods and apparatuses, such as those described in US and PCT applications 60/549,501; 11/069,361; 60/866,095; 11/940,673; 11/957,988; 12/337,554; 61/248,775; 61/259,011; 61/308,897; 61/310,700; 61/314,370; 61/314,392; 61/329,076; 61/329,198; 61/331,816; 61/352,782; 61/361,998; 61/377,854; 61/386,961; 61/389,233; PCT/US2010/051417; PCT/US2010/055729; 61/454,560; PCT/US2011/28746; 61/468,575; PCT/US2011/39349; 13/249,994; 13/399,733; 13/503674; 61/639,827,; 61/691,913; 61/639,827; 61/715,791; each of which is incorporated herein by reference.

### BACKGROUND

### Brief Description of the Figures

FIG. 1 is a schematic illustration of an example embodiment that uses scalar or vector magnetometers in a synthetic gradiometer configuration.

FIG. 2 is a schematic illustration of an example embodiment of MNPs SPMR measurement system.

FIG. 3 is a schematic illustration of an example embodiment of MNPs SPMR measurement system.

FIG. 4 is a schematic illustration of an example embodiment with a magnetically shielded enclosure.

FIG. 5 is a schematic illustration of an example embodiment.

FIG. 6 is a schematic illustration of an example embodiment.

### DESCRIPTION OF INVENTION

Various apparatuses for performing magnetic relaxometry measurements are described in the patent applications incorporated by reference above. Many of the apparatuses use superconducting quantum interference devices (SQUIDs) in combination with gradiometers to sense magnetic fields. Embodiments of the present invention provides methods and apparatuses that use atomic magnetometers (AMs) to make magnetic relaxometry measurements. Measurement cycles like those described in the incorporated applications can be used with the present invention.

There are many different types of AMs; one significant characteristic that differentiates them from SQUID-based magnetic sensors is that the measurement of the field with an atomic magnetometer is an absolute measurement. This makes their use in building “true” gradiometer configurations extremely difficult, but synthetic type of gradiometers can be realized in practice. Signals produced by dc SuperParaMagnetic Relaxometry (SPMR) of magnetic nanoparticles range from nT to sub-pT range or 3 to 4 orders of magnitude at a typical distance of 1 cm.

Several example embodiments are described herein. For ease of description, single channel apparatuses are described. The invention contemplates multiple channel apparatuses, and those skilled in the art appreciate how to convert the single channel apparatuses described herein to multiple channel apparatuses.

### Example Embodiment

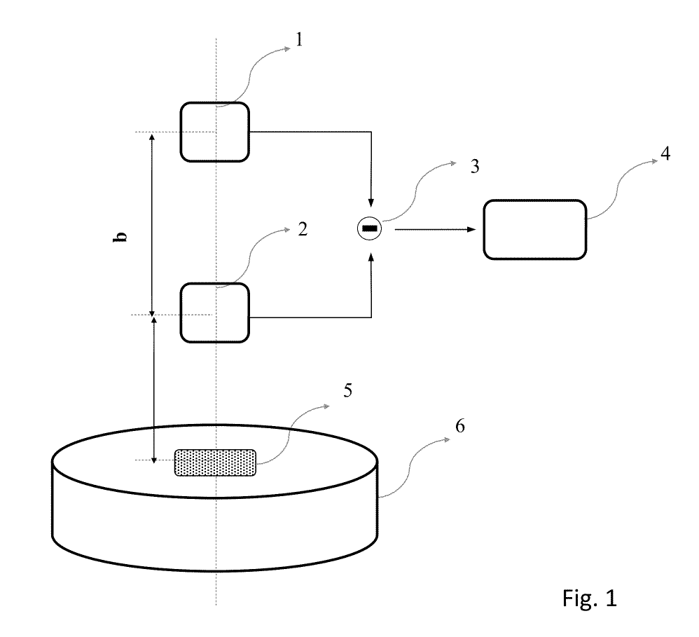

FIG. 1 is a schematic illustration of an example embodiment that uses scalar or vector magnetometers in a synthetic gradiometer configuration. Shown is first order gradiometer. Both magnetometers work in self-oscillating mode. The frequency of Larmor precession of atomic spins in Earth MF (0.5 Gauss) is about 350 KHz for Rb magnetometer with effective gyromagnetic ratio of 700 KHz/Gauss (or 7 Hz/nT). The base of gradiometer b can be chosen in a way that Channel 1 sees the MNP-SPMR (Magnetic NanoParticle-SuperParamagnetic Magnetic Relaxometry) signal that is at least an order of magnitude smaller signal than Channel 2. In practice, when pulsing the polarizing MF by magnetic field generating system (6) the magnetometers are out of the self-oscillating mode and do not work since the atomic polarization is destroyed. Once the field is off, the self-oscillation mode for (1) and (2) is established and a difference between their frequencies can be measured by subtracting them by a subtracting circuit (3). The signal conditioning, data acquisition, and processing can be done in a processing system (4). The difference signal will be produced mainly by the SPMR of MNP sample (5).

### Example Embodiment

An example embodiment uses “zero” field AMs by compensating (zeroing) environmental magnetic fields in a given bandwidth. The highest sensitivity AMs work at “zero” MFs. Those are called SERF (Spin Exchange Relaxation Free) magnetometers. In practical applications of SERFs, “zero” field means nT fields and it depends on the application since different applications require different bandwidth of operation. The sensitivity of SERF AM drops significantly with increasing the dc MF since the linewidth of the magnetic resonance increases and this lead to decreasing the amplitude of the magnetic signal coming from measurement the spin state of the alkali atomic ensemble.

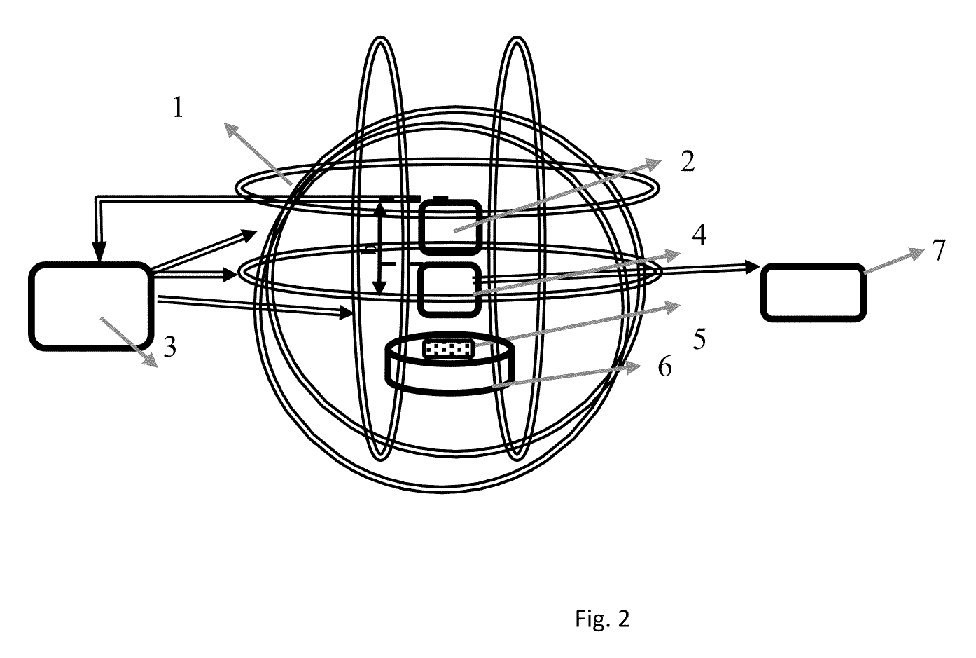

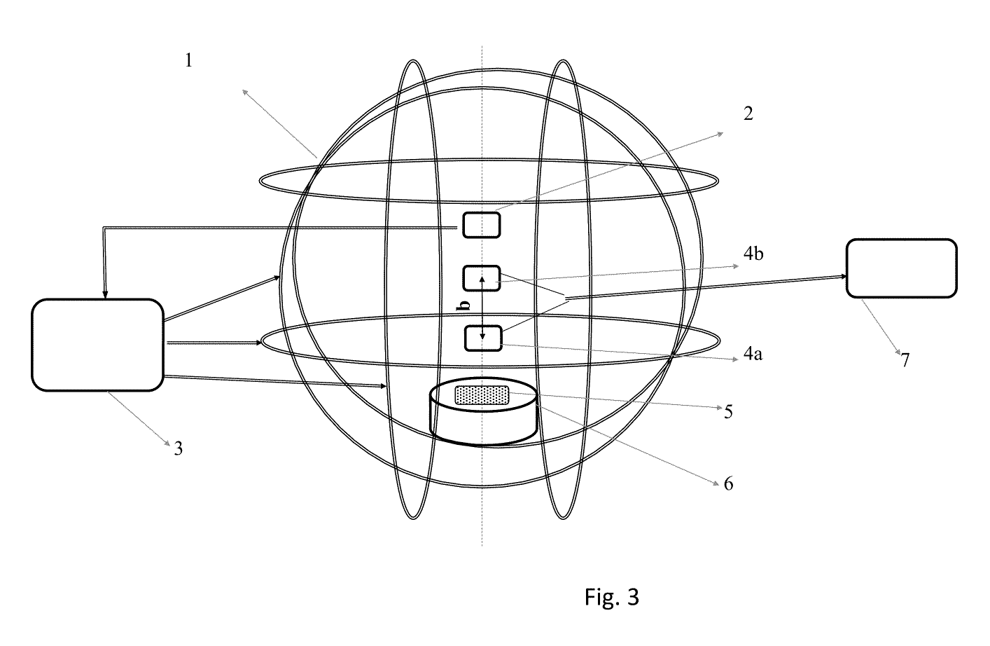

FIGS. 2 and 3 provide schematic illustrations of two example embodiments of MNPs SPMR measurement systems.

In the system shown in FIG. 2, a magnetometer (either single or up to 3-axis type) (4) is used to measure the magnetic field produced by ensemble of MNPs (5) when undergoing SPMR caused by switching off the polarization field created by coil system (6). The coil system can be a different type than the one shown (3-axis Helmholtz configuration). A three-axis magnetometer (2) is used to measure the environmental magnetic field. The distance b between the magnetometers (4) and (2) is chosen to be such that the field produced by MNPs is vanishingly small at the position of (2). The three MF components measured by (2) are fed as error signals to the current drivers for the Helmholtz coils (3). A PID control is also added to the zeroing field loop (2-3). The field compensating system creates a homogeneous volume of zero MF (nT to x10 nT) that includes (2) and (4). The field compensating system works in a pulsed mode—when (6) produces the polarizing field it is off, and it triggers on when the field is switched off. The SPMR signal is digitized in the acquisition module (7).

### Example Embodiment

The example embodiment shown in FIG. 3 comprises a system similar to that in FIG. 2. A significant difference being that instead of magnetometer (4) from FIG. 2, a first order gradiometer is used that is formed by (4a) and (4b) magnetometers. The outputs of the magnetometers are subtracted from each other and the resulting signal is fed to the acquisition module (7). The gradiometer lowers the detection limit of number of MNPs.

### Example Embodiment

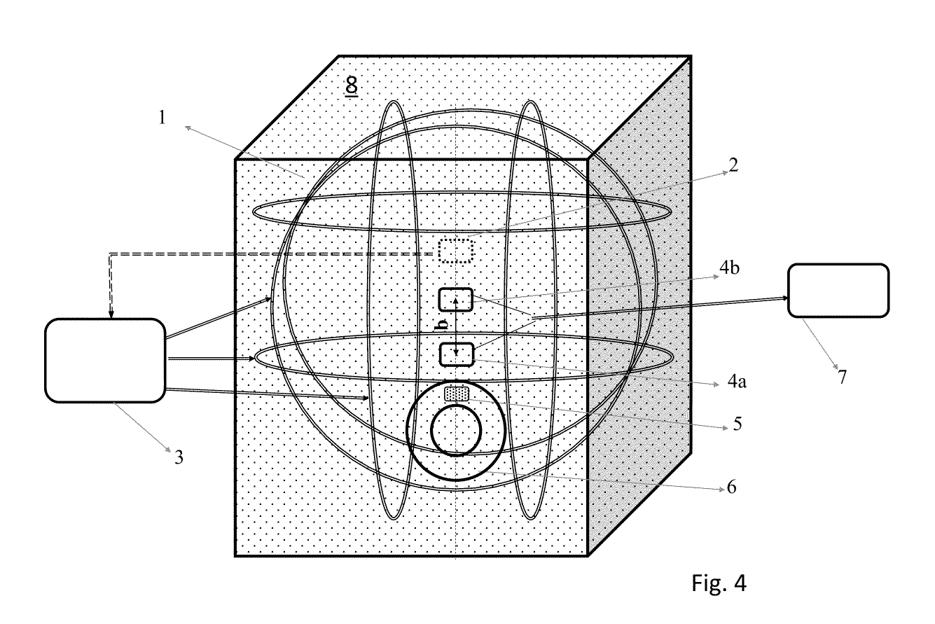

A magnetically shielded enclosure can help mitigate problems of existing large environmental MF gradients, noisy environments that includes interference from different sources, as well, using a simpler field cancelation technique. FIG. 4 is a schematic illustration of such an example embodiment.

The system presented in FIG. 4 is similar to the system from FIG. 3 with several differences. The whole system from FIG. 3 is enclosed in a cube shaped magnetic shield (8) made of a high permeability material (for example, mu-metal, etc.). The shape of the shield is not critical but highly symmetric shields are generally preferable. A role of the shield is to screen external magnetic fields in its inner volume. Typical field reduction of a single layer shield ranges between 100 to 1000 times depending on its characteristics. In order to compensate the already attenuated field inside the shield volume a system of 3D Helmholtz coils is used. Another difference is that the reference channel (2) might not be needed in some applications and only slight modifications to the currents of the Helmholtz coils have to be made offline to keep the magnetic field at the sensor positions in a specified range. Another difference is that instead of open geometry coil for magnetizing the MNPs a closed shape toroid coil (6) is used. The sample is placed inside the coil. The change of the coil geometry is beneficial since the field from an open geometry coil can magnetize the magnetic shield and thus create large constantly changing gradients at the sensors' positions. Another difference is that the MNPs axis of magnetization would be perpendicular to the axes from the previously shown cases.

In some magnetic relaxometry apparatuses described in the related applications, coils are used to impose a uniform magnetic field upon a sample, and superconducting quantum interference devices (SQUIDs) to sense the magnetic fields representative of the relaxation of the magnetization of the sample. The magnetic field imposed during magnetization of the sample is typically much larger than that sensed in measuring the magnetic relaxation of the sample. SQUIDs subjected to such a large magnetization field typically require time to recover and be able to sense the small relaxation fields. The recovery time can be longer than the time the relaxation field is present, making the desired measurement not possible.

Some example apparatuses have used gradiometers wound to reject uniform fields. The SQUIDs then primarily measure nonuniform fields. A sample placed near the gradiometers will present a nonuniform magnetic field to the gradiometers (since the coils of a gradiometer are at significantly different distances from the sample—the first coil is very close, but the next coil is several times father away).

In a system with gradiometer-coupled SQUID sensors, the magnetizing coils can be configured as Helmholtz coils. The Helmholtz coils can be configured such that they supply a substantially uniform magnetic field in the region of the sample and the gradiometers. The uniform field is sufficient magnetize the sample, but is substantially rejected by the gradiometers. Consequently, the SQUIDs are not substantially affected by the magnetization field and the measurement can be made very soon after removal of the magnetization field.

Helmholtz coils in such a configuration must be large relative to the desired sample volume and the SQUID/gradiometer system. Large coils require large amounts of space, and require large currents to generate the desired magnetic fields. The size and power required increases as the desired sample volume increases, which presents a challenge for efficient instruments for use with human subjects.

Relatively small coils, e.g., with diameter one to two times the size of the desired sample region, can supply the desired magnetization field with lower power and reduced space requirements. Such coils can be configured in pairs—one coil on each side of the sample; or can be configured as a single coil—placed on any side of the sample. Small coils, and single coils, will subject the gradiometers to nonuniform fields during the magnetization phase of the measurement, producing large currents in the gradiometers and SQUIDs. These currents should be dissipated before the sensitive measurement can be made.

A gradiometer can have a cryoswitch mounted with it, such that current in the gradiometer passes through the cryoswitch. The cryoswitch can be maintained in a superconducting state during measurement times, such that the gradiometer/SQUID sensing operation is not affected by the cryoswitch. The cryoswitch can be placed in a normal (not superconducting) state at a time during or after the end of the magnetization phase, and maintained in that state for a short time after the end of the magnetization phase. Currents in the gradiometer due to the nonuniform fields produced by the magnetization coils will be rapidly dissipated by the cryoswitch in its normal state. After sufficient time for the currents to dissipate (e.g., a few microseconds), the cryoswitch can be returned to its superconducting state and the sensitive measurement of the relaxing magnetic field of the sample can be made. The few microseconds required for the cryoswitch to dissipate the currents is much less than the many milliseconds (or longer) required for the SQUIDS to recover from the large magnetization fields.

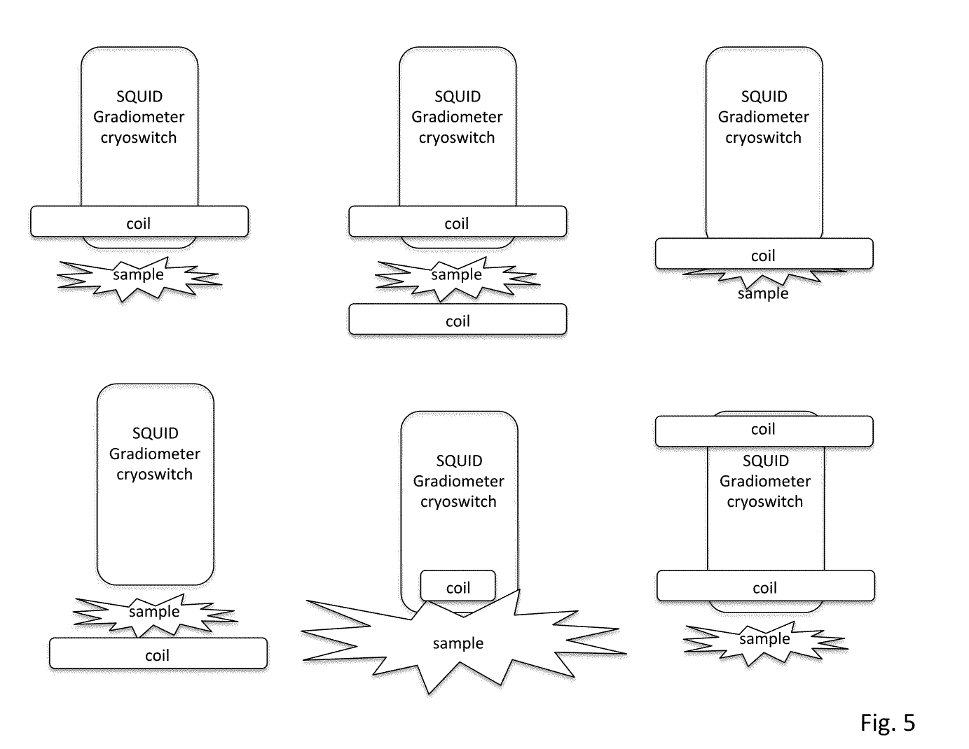

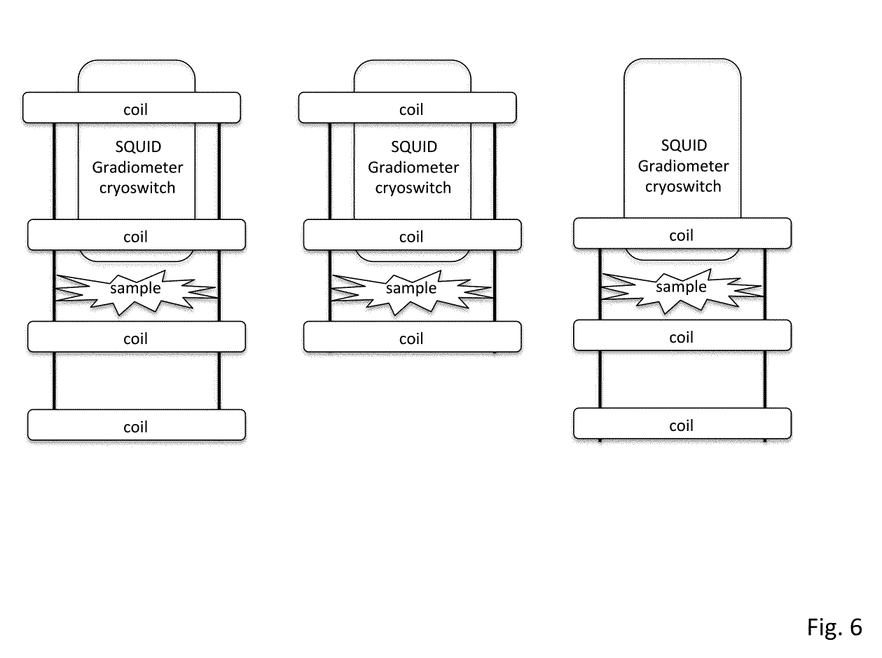

The use of cryoswitches to dissipate current from nonuniform magnetization fields allows flexibility in configuring the magnetization coils, for example to accommodate various sample positioning constraints, or sample sizes, or magnetic field uniformity and direction preferences for system performance. FIGS. 5, 6 provides schematic illustrations of various configurations that can be suitable. In the figures, the sensor subsystem is depicted as a SQUID-based system; other sensor embodiments such as atomic magnetometers as described above can also be suitable. Suitable coils can comprise various configurations. As examples: one or more substantially circular loops of electrically conducting material such as wire, connected in parallel or series; one or more loops of electrically conducting material, defining a roughly rectangular shape, connected in parallel or series; one or more spirals; multiple coils placed side by side; etc.

The present inventions have been described in the context of various example embodiments. The inventions include variations and combinations that will be apparent to those skilled in the art upon review of the present descriptions and figures.

We claim:

1. An apparatus configured for magnetic relaxometry measurements, comprising:
(a) a magnetizing subsystem, configured to magnetize superparamagnetic nanoparticles in a sample disposed in a predetermined relationship to the magnetizing subsystem;
(b) a first atomic atomic magnetometer, disposed relative to the sample such that the first atomic magnetometer detects a magnetic signal produced by magnetized nanoparticles in the sample;
(c) a second atomic magnetometer, disposed relative to the sample and the first atomic magnetometer such that the second atomic magnetometer detects the magnetic signal no more than 50% of the strength of that detected by the first atomic magnetometer;
(d) an analysis system, configured to determine the magnetic field produced by the nanoparticles from the signals detected by the first and second atomic magnetometers.

2. A system as in claim 1, wherein the magnetizing subsystem comprises a toroidal coil, configured to allow a sample to be placed within the torus.

3. A system as in claim 1, further comprising one or more Helmholtz coil systems, configured to produce a magnetic field in the region where the sample is disposed that substantially cancels all magnetic fields except the magnetic field of the magnetizing subsystem.

4. A system as in claim 3, further comprising a magnetometer configured to sense magnetic fields other than the magnetic field of the magnetizing subsystem, and wherein the Helmholtz coils are driven responsive to the magnetic fields sensed by the magnetometer.

5. A system as in claim 1, further comprising a magnetic shield enclosure, and wherein the magnetizing subsystem and the first and second atomic magnetometers are disposed within the magnetic shield enclosure.

6. A system as in claim 1, wherein the magnetizing subsystem comprises four coils, where the four coils are spaced apart along an axis through the center of each coil, and wherein apparatus is configured such that the sample is disposed between the middle two of the four coils.

7. An apparatus suitable for magnetic relaxometry measurements of a sample, comprising:
(a) a magnetizing subsystem, configured to magnetize superparamagnetic nanoparticles in a sample disposed in a predetermined relationship to the magnetizing subsystem;
(b) a gradiometer, disposed relative to the sample such that the gradiometer is sensitive to magnetic fields produced from the sample and substantially insensitive to magnetic fields produced from locations other than the sample;
(c) a cryoswitch, connected to the gradiometer such that the cryoswitch, when in normal state, dissipates current from the gradiometer responsive to sensed magnetic fields;
(d) a superconducting quantum interference device, connected to the gradiometer and the cryoswitch such that it detects magnetic fields sensed by the gradiometer;
(e) a control system, configured to energize the magnetizing subsystem for a first predetermined time, place the cryoswitch into normal state for a time sufficient to dissipate gradiometer current responsive to the magnetizing subsystem, place the cryoswitch into superconducting state and detect a magnetic field sensed by the superconducting quantum interference device while the cryoswitch is in superconducting state.

8. A system as in claim 7, wherein the magnetizing subsystem comprises a toroidal coil, configured to allow a sample to be placed within the torus.

9. A system as in claim 7, wherein the magnetizing subsystem comprises four coils, where the four coils are spaced apart along an axis through the center of each coil, and wherein apparatus is configured such that the sample is disposed between the middle two of the four coils.
